(19) United States
(12) Patent Application Publication
(10) Pub. No.: US 2025/0326077 A1
(43) Pub. Date: Oct. 23, 2025

(54) SINGLE ACTUATOR PANEL LIFT AND CLAMP SYSTEM

(71) Applicant: Orbotech Ltd., Yavne (IL)

(72) Inventor: Asher KATZ, Tel-Aviv (IL)

(21) Appl. No.: 18/640,913

(22) Filed: Apr. 19, 2024

(51) Int. Cl. B23Q 3/06

(52) U.S. Cl. CPC B23Q 3/069; B23Q 3/062; B23Q 2703/10

(57) ABSTRACT

A lift and clamp system for an electronic component includes a table for supporting the electronic component on a top surface thereof. The system also includes a single actuator. The system further includes an actuator plate operatively coupled to the single actuator, wherein the actuator plate is vertically moveable. The system yet further includes a plurality of lift pins extending upwardly from the actuator plate, wherein vertical movement of the actuator plate vertically adjusts the vertical position of the electronic component supported on at least one of the plurality of lift pins, wherein vertical movement of the actuator plate selectively clamps and unclamps the electronic component to the table.

### FIELD OF THE INVENTION

The embodiments described herein relate to a panel and wafer handling apparatus in general and, more specifically, to manufacturing and inspection systems employing lift pins and clamps apparatus.

### BACKGROUND

Inspection processes are used at various steps during a manufacturing process to detect defects on wafers, panels or other electronic components to promote higher yield and quality in the manufacturing process, thereby obtaining higher profits. Additionally, processing steps may be performed on the electronic component, such as laser drilling of micro vias and deposition on a substrate.

Many fabrications, metrology and defect inspection processes require loading wafers, panels or the like on a process machine table. This is often done by a robot with an end effector in the shape of a fork. The robot puts the wafer or panel on lift pins which extend upwardly from the table. Traditionally, a first actuator system is required to adjust the vertical height of the wafer or panel with the lift pins and a separate, second actuator system is required to clamp the wafer or panel to the table. The lift pin actuator system and the clamping actuator system must be synchronized during operation.

The requirement of two separate actuator systems poses challenges and disadvantages related to complexity, cost and the time needed to synchronize operational actions, thereby effecting the overall efficiency and reliability of the machine.

### SUMMARY OF THE DISCLOSURE

According to one aspect of the disclosure, a lift and clamp system for an electronic component includes a table for supporting the electronic component on a top surface thereof. The system also includes a single actuator. The system further includes an actuator plate operatively coupled to the single actuator, wherein the actuator plate is vertically moveable. The system yet further includes a plurality of lift pins extending upwardly from the actuator plate, wherein vertical movement of the actuator plate vertically adjusts the vertical position of the electronic component supported on at least one of the plurality of lift pins, wherein vertical movement of the actuator plate selectively clamps and unclamps the electronic component to the table.

According to another aspect of the disclosure, a lift and clamp system for an electronic component includes a table for supporting the electronic component on a top surface thereof. The system also includes a single actuator. The system further includes an actuator plate operatively coupled to the single actuator, wherein the actuator plate is vertically moveable. The system yet further includes a plurality of lift pins extending upwardly from the actuator plate, wherein vertical movement of the actuator plate vertically adjusts the vertical position of the electronic component supported on at least one of the plurality of lift pins, wherein vertical movement of the actuator plate selectively clamps and unclamps the electronic component to the table, wherein the table defines a plurality of holes extending completely vertically through the table, wherein at least one of the lift pins is positioned within one of the plurality of holes, wherein the plurality of lift pins comprises a plurality of support lift pins and at least one clamp lift pin, wherein the plurality of support lift pins have a top end for supporting the electronic component, wherein each of the at least one clamp lift pin includes a clamp device secured to a top portion thereof.

According to another aspect of the disclosure, a method of loading and clamping an electronic component for processing is provided. The method includes adjusting a top portion of plurality of support lift pins and a top portion of at least one clamp lift pin to an upward position spaced from a top surface of a table with a single actuator, wherein the plurality of support lift pins and the at least one clamp lift pin are connected to, and project upwardly from, an actuator plate. The method also includes loading an electronic component on to the top portion of the plurality of support pins. The method further includes lowering the actuator plate with the single actuator to simultaneously move the plurality of support lift pins and the clamp lift pin to place the electronic component in contact with the top surface of the table. The method also includes further lowering the actuator plate with the single actuator to simultaneously move the plurality of support lift pins and the clamp lift pin to clamp the electronic component to the table with a clamp device connected to the top portion of the clamp lift pin.

These aspects and other advantages and features are apparent from the following description taken in conjunction with the drawings.

### BRIEF DESCRIPTION OF THE DRAWINGS

The subject matter that is regarded as embodiments of the invention is particularly pointed out and distinctly claimed in the claims at the conclusion of the specification. The features and advantages of the disclosed embodiments are apparent from the following detailed description taken in conjunction with the accompanying drawings in which:

FIG. 1 is a schematic illustration of a single actuator panel lift and clamp system shown in a first operating position;

FIG. 2 is a schematic illustration of the single actuator panel lift and clamp system shown in a second operating position; and

FIG. 3 is a schematic illustration of the single actuator panel lift and clamp system shown in a third operating position.

### DETAILED DESCRIPTION

Referring to the drawings, where the invention will be described with reference to specific embodiments, it is to be understood that the disclosed embodiments are merely examples of the invention that may be embodied in various and alternative forms. The drawings are not necessarily to scale, as some features may be exaggerated, reduced or simplified to show details of particular components. Therefore, specific structural and functional details disclosed herein and illustrated in the drawings are not to be interpreted as limiting, but merely as a representative basis for teaching one skilled in the art to variously employ the invention.

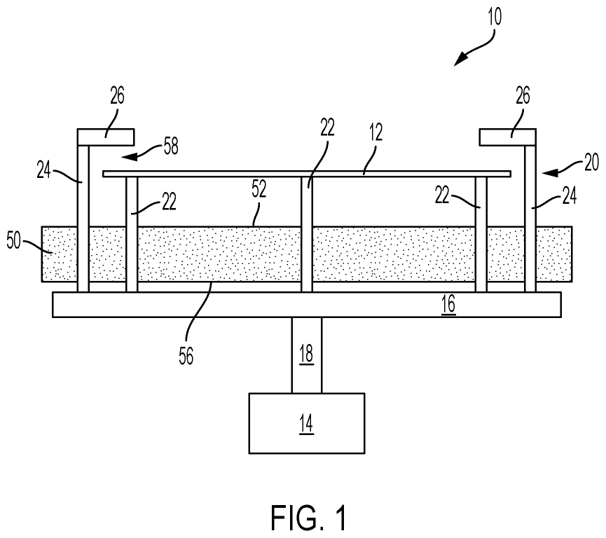

Referring to FIG. 1, a single actuator lift and clamp system is schematically shown and generally referenced with numeral 10. The lift and clamp system 10 is configured to be used in the manufacture and inspection of electronic components. The electronic components may be any suitable wafer/substrate suitable substrates, flat panels for flat panel displays, solar panels, printed circuit boards, film layers, reticles or any other suitable object. Therefore, the term “electronic components”, as used herein, refers generically to any of the aforementioned objects, but is not limited thereto.

As disclosed herein, the lift and clamp system 10 is utilized to support, positionally adjust and clamp an electronic component 12 thereto with a single actuator 14 and in a synchronized manner. Therefore, vertical adjustment and clamping of the electronic component 12 relative to a table 50 is performed with a single, common actuator mechanism.

The lift and clamp system 10 includes the actuator 14 operatively connected to an actuator plate 16. The actuator 14 may be powered pneumatically, hydraulically, electromechanically and/or in any other suitable manner. The actuator plate 16 is vertically adjusted based on operation of the actuator 14. The actuator 14 may include an actuator rod 18 directly or indirectly coupled to the actuator plate 16 to facilitate vertical adjustment of the actuator plate 16.

A plurality of lift pins 20 are secured to the actuator plate 16 and project upwardly therefrom. The plurality of lift pins 20 may be operatively coupled to the actuator plate 16 or integrally formed therewith. The plurality of lift pins 20 may be of any suitable material for contact with the particular type of the electronic component 12 being supported and clamped. Additionally, the plurality of lift pins 20 may be formed in any suitable shape, such as with a substantially circular, rectangular, or other cross-sectional geometry. The plurality of lift pins 20 are categorized in two groups. In particular, the overall plurality of lift pins 20 includes a plurality of support lift pins 22 and a plurality of clamp lift pins 24. The plurality of support lift pins 22 are positioned to collectively support the electronic component 12 on a top surface of the support lift pins 22. Each of the clamp lift pins 24 have a clamp device 26 disposed at a top portion of the clamp lift pins 24. Each clamp device 26 may be operatively coupled to one of the clamp lift pins 24 or may be integrally formed therewith.

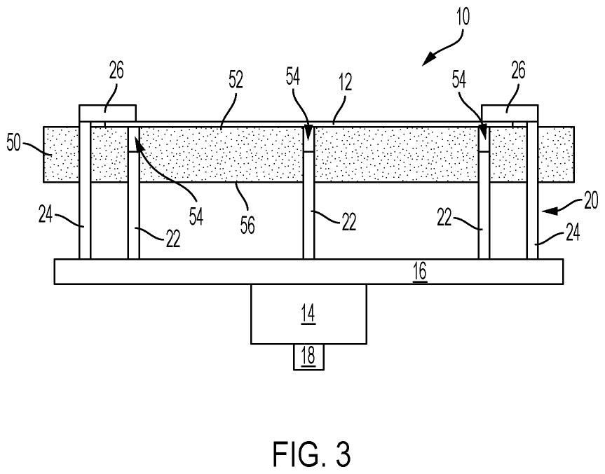

The single actuator lift and clamp system 10 includes the table 50, which is configured to support the electronic component 12 on a top surface 52 thereof. The table 50 may include various features known in the art of wafer or panel inspection and manufacturing. For example, a gas vacuum system may be incorporated into the table 50 to assist with retention and/or flattening of the electronic component 12 when supported by the table 50. The table 50 remains vertically stationary relative to the actuator plate 16. A plurality of holes 54 (best illustrated in FIG. 3) are defined within the table 50 and extend completely vertically through the table 50. In particular, each of the holes 54 extends between and through the top surface 52 and a bottom surface 56 of the table 50. Each hole 54 is sized to receive one of the lift pins 20 therethrough. However, in some embodiments, only the support lift pins 22 extend into the plurality of holes 54, while the clamp lift pins are positioned laterally outward of, or adjacent to, side edges of the table 50.

As described above, the lift pins 20 are fixed to the actuator plate 16. During vertical movement of the actuator plate 16, the lift pins 20 are moved vertically through the holes 54 to vertically adjust the position of the top of each lift pin 20. Bearings or other stabilizing components and lubricant (not shown) may be disposed between the outer surface of the lift pins 20 and the inner walls of the holes 54 to stabilize the movement of the lift pins 20 in some embodiments.

As shown in FIG. 1, an initial, upward position of the actuator plate 16—and therefore the top of each of the lift pins 20 creates a spacing between the top of the support lift pins 22 and the top surface 52 of the table 50. Additionally, the clamp lift pins 24 are longer than the support lift pins 22, thereby creating a vertical gap 58 between the clamp devices 56 and the top of the support lift pin 22. The above-described relative spacing allows a robot or other device to insert the electronic component 12 on to the top of the support lift pins 22 in a substantially horizontal manner between the clamp devices 26 and the support lift pins 22. Once the electronic component 12 is placed on the top of the support lift pins 22, the electronic component remains unclamped due to the vertical gap 58 and also vertically spaced from the top surface 52 of the table 50.

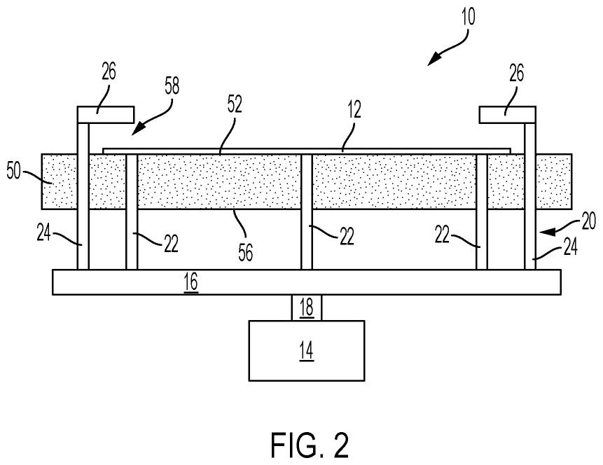

Referring now to FIG. 2, the actuator plate 16 is shown in a second operating position. In the illustrated position, the actuator 14 has vertically adjusted the actuator rod 18, and therefore all of the lift pins 20, the electronic component 12 and the clamp devices 26, in a downward direction-relative to the loading position of FIG. 1—to an extent necessary to place the electronic component 12 in contact with the top surface 52 of the table 50. The actuator plate 16, all lift pins 20 and the clamp devices 26 vertically move a common distance during operation due to actuation by a single, common actuator. This common vertical movement maintains the vertical gap 58 between the clamp devices 26 and the top surface 52 of the table 50 in the position shown in FIG. 2.

Referring now to FIG. 3, the actuator plate 16 is shown in a third operating position. In the illustrated position, the actuator 14 has vertically adjusted the actuator rod 18, and therefore all of the lift pins 20 and the clamp devices 26, in a downward direction-relative to the loading position of FIG. 1 and intermediate position of FIG. 2—to an extent necessary to place the clamp devices 26 in contact with the top of the electronic component 12. In the clamp position of FIG. 3, the clamp devices 26 secure the electronic component 12 to the table 50 for inspection and/or processing. As shown, the support lift pins 22 have continued to move downwardly within the holes 54 of the table 50 while the clamp lift pins 24 are moved sufficiently downward to clamp the electronic component 12.

As described herein, the lift and clamp system 10 carries out the vertical adjustment required to place the electronic component 12 on the top surface 52 of the table 50 and clamping with the single, common actuator 14, and in a single, synchronized movement. Unloading of the electronic component 12 is simply done in the reverse order as that described above. Therefore, challenges associated with timing the lifting movement and the clamping movement with different mechanisms and/or actuators are eliminated.

While the invention has been described in detail in connection with only a limited number of embodiments, it is to be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Moreover, any feature, element, component or advantage of any one embodiment can be used on any of the other embodiments. Accordingly, the invention is not to be seen as limited by the foregoing description.

What is claimed is:

1. A lift and clamp system for an electronic component comprising:
a table for supporting the electronic component on a top surface thereof;
a single actuator;
an actuator plate operatively coupled to the single actuator, wherein the actuator plate is vertically moveable; and
a plurality of lift pins extending upwardly from the actuator plate, wherein vertical movement of the actuator plate vertically adjusts the vertical position of the electronic component supported on at least one of the plurality of lift pins, wherein vertical movement of the actuator plate selectively clamps and unclamps the electronic component to the table.

2. The lift and clamp system of claim 1, wherein the plurality of lift pins comprises a plurality of support lift pins and at least one clamp lift pin, wherein the plurality of support lift pins have a top end for supporting the electronic component, wherein each of the at least one clamp lift pin includes a clamp device secured to a top portion thereof.

3. The lift and clamp system of claim 2, wherein the table defines a plurality of holes extending completely vertically through the table, wherein each of the support lift pins is positioned within one of the plurality of holes.

4. The lift and clamp system of claim 3, wherein the at least one clamp lift pin is positioned within one of the plurality of holes.

5. The lift and clamp system of claim 2, wherein the clamp device is integrally formed with the clamp lift pin.

6. The lift and clamp system of claim 2, wherein the clamp device is operatively coupled to the clamp lift pin.

7. The lift and clamp system of claim 2, wherein the plurality of lift pins are integrally formed with the actuator plate.

8. The lift and clamp system of claim 2, wherein the plurality of lift pins are operatively coupled to the actuator plate.

9. The lift and clamp system of claim 2, wherein the top of the support lift pins is vertically offset below the top of the clamp lift pin(s) to define a vertical gap therebetween.

10. The lift and clamp system of claim 1, wherein the electronic component is at least one of a wafer, a substrate, a flat panel, a solar panel, a printed circuit board, a film layer, and a reticle.

11. A lift and clamp system for an electronic component comprising:
a table for supporting the electronic component on a top surface thereof;
a single actuator;
an actuator plate operatively coupled to the single actuator, wherein the actuator plate is vertically moveable; and
a plurality of lift pins extending upwardly from the actuator plate, wherein vertical movement of the actuator plate vertically adjusts the vertical position of the electronic component supported on at least one of the plurality of lift pins, wherein vertical movement of the actuator plate selectively clamps and unclamps the electronic component to the table, wherein the table defines a plurality of holes extending completely vertically through the table, wherein at least one of the lift pins is positioned within one of the plurality of holes, wherein the plurality of lift pins comprises a plurality of support lift pins and at least one clamp lift pin, wherein the plurality of support lift pins have a top end for supporting the electronic component, wherein each of the at least one clamp lift pin includes a clamp device secured to a top portion thereof.

12. The lift and clamp system of claim 11, wherein the clamp device is integrally formed with the clamp lift pin.

13. The lift and clamp system of claim 11, wherein the clamp device is operatively coupled to the clamp lift pin.

14. The lift and clamp system of claim 11, wherein the plurality of lift pins are integrally formed with the actuator plate.

15. The lift and clamp system of claim 11, wherein the plurality of lift pins are operatively coupled to the actuator plate.

16. The lift and clamp system of claim 11, wherein the top of the support lift pins is vertically offset below the top of the clamp lift pin(s) to define a vertical gap therebetween.

17. The lift and clamp system of claim 11, wherein the electronic component is at least one of a wafer, a substrate, a flat panel, a solar panel, a printed circuit board, a film layer, and a reticle.

18. A method of loading and clamping an electronic component for processing:
adjusting a top portion of plurality of support lift pins and a top portion of at least one clamp lift pin to an upward position spaced from a top surface of a table with a single actuator, wherein the plurality of support lift pins and the at least one clamp lift pin are connected to, and project upwardly from, an actuator plate;
loading an electronic component on to the top portion of the plurality of support pins;
lowering the actuator plate with the single actuator to simultaneously move the plurality of support lift pins and the clamp lift pin to place the electronic component in contact with the top surface of the table; and
further lowering the actuator plate with the single actuator to simultaneously move the plurality of support lift pins and the clamp lift pin to clamp the electronic component to the table with a clamp device connected to the top portion of the clamp lift pin.

19. The method of claim 18, wherein adjusting the plurality of support lift pins and the at least one clamp pin comprises vertically moving each of the plurality of support lift pins and the at least one clamp pin through a respective one of a plurality of holes defined by the table.
